(19) United States
(12) Patent Application Publication
(10) Pub. No.: US 2026/0221301 A1
(43) Pub. Date: Jul. 30, 2026

(54) GPU-Accelerated Real-Time Digital Twin with Divergence Detection for Control of Land-Based Nuclear Reactors

(71) Applicant: Gregory Alavro Forero, Dallas, TX (US)

(72) Inventor: Gregory Alavro Forero, Dallas, TX (US)

(73) Assignees: Gregory Alavro Forero, Dallas, TX (US); HGP Intelligent Energy, LLC, Dallas, TX (US)

(21) Appl. No.: 19/574,854

(22) Filed: Mar. 23, 2026

(51) Int. Cl. G21D 3/00; G06F 30/28; G21D 3/08

(52) U.S. Cl. CPC G21D 3/002; G06F 30/28; G21D 3/08

(57) ABSTRACT

A GPU-accelerated digital twin system for real-time thermal-hydraulic simulation and closed-loop control of land-based pressurized water reactor nuclear power plants. The system comprises a GPU-native Crank-Nicolson plus Thomas algorithm solver computing radial temperature distributions across 264 fuel pins with 40 radial nodes each, supporting 16 distinct cladding material configurations including ZIRLO, chromium-coated zirconium alloy, iron-chromium-aluminum alloy, silicon carbide composites, functionally graded materials, and ceramic-metallic cermets. Six-group delayed neutron kinetics with Doppler and moderator temperature reactivity feedback and a proportional-integral controller modulate control rod position and coolant flow to maintain 800 MWt target power. Integrated loss-of-coolant accident and reactivity-insertion accident transient modules ensure compliance with 10 CFR 50.46 safety limits. The system achieves p95 latency below 10 milliseconds, enabling real-time monitoring, control, and predictive safety assessment for medium naval-derived reactor land-based deployments.

### CROSS-REFERENCE TO RELATED APPLICATIONS

This application is related to co-pending U.S. patent application Ser. No. 19/563,971, filed Mar. 11, 2026, entitled “GPU-Accelerated Digital Twin System for Real-Time Thermal-Hydraulic Simulation and Control of Space Nuclear Reactors,” which is incorporated herein by reference in its entirety.

### FIELD OF THE INVENTION

This invention relates to real-time simulation and control systems for land-based pressurized water nuclear reactors, and more particularly to GPU-accelerated digital twin architectures for closed-loop power control, multi-material cladding thermal analysis, and real-time accident transient assessment of medium naval-derived reactor (MNDR) power plants.

### BACKGROUND OF THE INVENTION

Land-based deployment of naval-derived pressurized water reactors (PWRs) offers a pathway to rapidly scalable, factory-modular nuclear energy for grid-connected power generation and industrial process heat. The medium naval-derived reactor (MNDR) concept adapts proven naval reactor technology for an 800 MWt land-based configuration using commercial-grade UO 2 fuel in a 17×17 lattice geometry. Effective real-time monitoring, control, and predictive safety assessment of such reactors requires physics-based digital twin simulation running at control-loop speeds on dedicated GPU hardware.

A critical challenge in advanced PWR design is the evaluation of multiple candidate cladding materials, including accident-tolerant fuel (ATF) cladding systems, under both normal operating conditions and design-basis accident scenarios. Sixteen distinct cladding configurations spanning conventional zirconium alloys, coated zirconium alloys, iron-chromium-aluminum alloys, silicon carbide composites, functionally graded materials, and ceramic-metallic cermets must be simultaneously evaluable by the digital twin to support material selection and regulatory compliance demonstration.

Several prior art approaches to nuclear reactor digital twins exist, but none address the specific requirements of land-based PWR real-time control with multi-material cladding analysis on GPU hardware.

### DESCRIPTION OF THE PRIOR ART

US20160247129A1 (GE Digital, 2016): General-purpose Digital Twin concept for industrial assets including rotating machinery and power generation equipment. Cloud-based data analytics and predictive maintenance for conventional industrial equipment. NOT nuclear-specific, NOT GPU-accelerated, does NOT support multi-material cladding analysis or accident transient simulation.

ARPA-E GEMINA Program (2020, $27M funding): Digital twin development for advanced terrestrial reactors including the Kairos FHR, Xe-100 HTGR, and BWRX-300. None achieve GPU real-time control latencies below 10 ms. None incorporate multi-material cladding property libraries with 16 or more configurations. None integrate real-time LOCA and RIA transient analysis within the digital twin control loop.

Argonne National Laboratory GNN Digital Twins (2024-2025): Graph neural network surrogate models trained on EBR-II experimental breeder reactor data for offline transient analysis. NOT real-time control systems, do NOT employ GPU-accelerated physics solvers. GNN approach substitutes learned approximations for first-principles physics, introducing unquantified prediction uncertainty unsuitable for safety-critical reactor control. Do NOT support multi-material cladding analysis.

INL/ISU AGN-201 Cloud Digital Twin (2023): Cloud-connected digital twin for the AGN-201 zero-power research reactor requiring continuous internet connectivity. Does NOT employ embedded GPU computing, does NOT support accident transient analysis, does NOT address multi-material cladding.

Idaho National Laboratory MOOSE/Griffin Framework (2023): Finite-element multiphysics framework for nuclear reactor simulation. Achieves high-fidelity results but requires high-performance computing clusters with simulation times orders of magnitude longer than real time. NOT suitable for real-time control applications.

NRC-approved thermal-hydraulic codes (RELAP5, TRACE): Industry-standard system-level thermal-hydraulic codes used for safety analysis. Execute on CPU hardware with simulation times far exceeding real time. NOT GPU-accelerated, NOT designed for real-time digital twin control applications, do NOT support simultaneous multi-material cladding evaluation within a single simulation framework.

Accordingly, no prior art teaches or suggests a GPU-native Crank-Nicolson plus Thomas algorithm solver for land-based PWR thermal-hydraulics with integrated multi-material cladding property evaluation across sixteen or more cladding configurations, combined with six-group delayed neutron kinetics, real-time LOCA and RIA transient analysis, and closed-loop power control, all achieving p95 latency below 10 milliseconds on GPU hardware.

### SUMMARY OF THE INVENTION

The present invention provides a GPU-accelerated digital twin system for land-based pressurized water reactors, specifically targeting medium naval-derived reactor (MNDR) configurations. The system addresses the deficiencies of the prior art by providing deterministic, physics-based, real-time simulation, closed-loop control, and predictive safety assessment on GPU hardware with integrated multi-material cladding analysis.

In one aspect, the invention comprises: (a) a GPU-native Crank-Nicolson temporal discretization with Thomas algorithm tridiagonal solver computing 264 fuel pin radial temperature profiles simultaneously in parallel across 40 radial nodes per pin spanning fuel, gap, and cladding regions; (b) a multi-material cladding thermal property library supporting sixteen distinct cladding configurations with temperature-dependent properties; (c) a six-group delayed neutron kinetics module with Doppler and moderator temperature reactivity feedback; (d) a Dittus-Boelter heat transfer correlation with mixing vane grid spacer enhancement for pressurized water coolant; (e) LOCA transient analysis with blowdown, refill, and reflood phases computing peak cladding temperature and cladding oxidation for 10 CFR 50.46 compliance; (f) RIA analysis with six-group point kinetics and Doppler feedback for NRC fuel enthalpy compliance; and (g) a closed-loop proportional-integral (PI) power controller modulating control rod position and coolant flow rate.

The system achieves a p95 computational latency below 10 milliseconds per time step, enabling true real-time control at a 10 ms control loop period.

### BRIEF DESCRIPTION OF THE DRAWINGS

FIG. 1 is a block diagram showing the GPU-accelerated digital twin system architecture including the GPU thermal solver, neutron kinetics module, multi-material cladding property library, LOCA and RIA accident transient modules, accident sequencing module, and closed-loop PI power controller with sensor input and actuator output interfaces to the physical MNDR reactor.

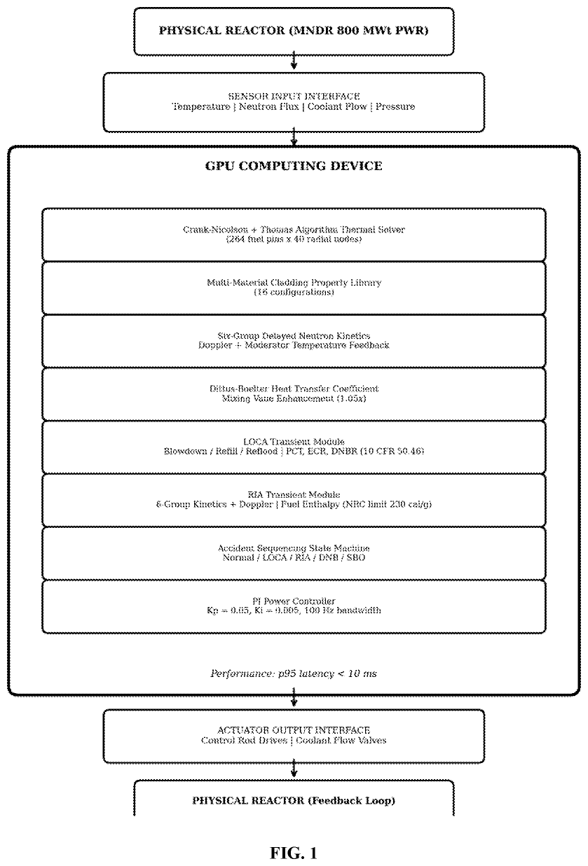

FIG. 2 is a graph showing representative steady-state radial temperature profiles for selected cladding configurations (ZIRLO, FeCrAl, SiC/SiC, CVD SiC), demonstrating the effect of different cladding materials on fuel centerline temperature, cladding inner temperature, cladding outer temperature, and coolant bulk temperature across the 40-node radial discretization.

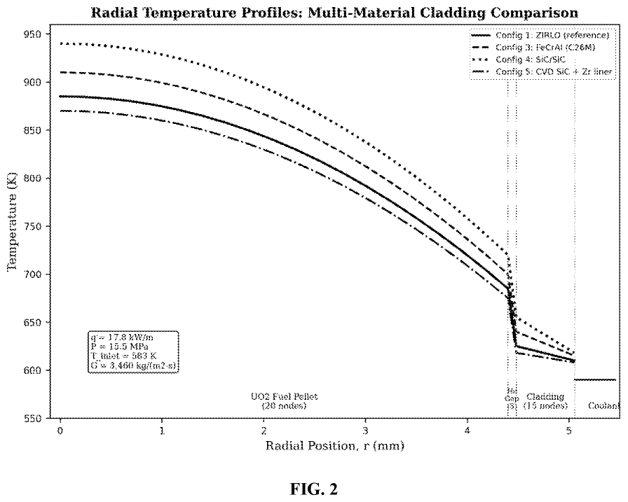

### DETAILED DESCRIPTION OF THE PREFERRED EMBODIMENTS

The following detailed description sets forth specific embodiments of the present invention. It will be appreciated that the invention may be practiced in ways other than those specifically described herein without departing from the spirit and scope of the invention as defined by the appended claims.

### MNDR Reactor Parameters

The preferred embodiment is configured for a medium naval-derived reactor (MNDR) land-based pressurized water reactor with the following design parameters: thermal power of 800 MWt; system pressure of 15.5 MPa; coolant inlet temperature of 583 K; coolant outlet temperature of 598 K; 69 fuel assemblies; 264 fuel pins per assembly in a 17 -by-17 square lattice with 25 guide tube and instrument tube positions; active fuel length of 3.6576 m (12 feet); pin pitch of 13.40 mm; total peaking factor Fq of 2.50; axial peaking factor Fz of 1.55; and linear heat rate of 17.8 kW/m.

### Fuel Pin Geometry

Each fuel pin comprises a solid cylindrical uranium dioxide (UO2) pellet with an outer radius of 4.40 mm, enriched to 4.95 weight percent uranium-235, at 95 percent of theoretical density (10,970kg/m3). A helium gas gap of 82.6 micrometer thickness separates the pellet from the cladding. The total cladding wall thickness is 571.5 micrometers. The resulting pin outer radius defines the hydraulic subchannel geometry for coolant flow analysis.

### UO2 Fuel Properties

The uranium dioxide fuel thermal conductivity follows the FRAPCON correlation: k=1/(A+B*T)+C*exp(−D/T), where A=0.0452 m*K/W, B=2.46e-4 m/W, C and D are radiation damage terms. The fuel density is 10,422 kg/m3(95 % TD), and the specific heat capacity follows temperature-dependent MATPRO correlations.

### Multi-Material Cladding Configurations

The digital twin supports sixteen cladding material configurations, each with fully temperature-dependent thermal properties:
Configuration 1 (ZIRLO Reference): Standard ZIRLO zirconium alloy with thermal conductivity k=7.51+2.09e-2*(T-273.15)−1.45e-5*(T-273.15)^2+7.67e-9*(T-273.15)^3 W/(m*K), density 6,560 kg/m3 .
Configuration 2 (Cr-coated ZIRLO): ZIRLO substrate with a 20 micrometer outer chromium coating. Chromium thermal conductivity k=93.9−0.0178*T W/(m*K), density 7,190 kg/m3. Hydrogen generation factor reduced to 0.05 relative to bare ZIRLO.
Configuration 3 (FeCrAl C26M): Iron-chromium-aluminum alloy with k=10.0+0.012*T W/(m*K), density 7,250 kg/m3. Hydrogen generation factor 0.02.
Configuration 4 (SiC/SiC Composite): Silicon carbide fiber-reinforced silicon carbide matrix with k=4,800/T W/(m*K), density 3,210 kg/m3. Hydrogen generation factor 0.001.
Configuration 5 (CVD SiC+Zr Liner): Chemical vapor deposition silicon carbide structural layer with a 47 micrometer zirconium inner liner for hermeticity. CVD SiC thermal conductivity k=52,000/T W/(m*K).
Configuration 6 (Mo-lined ZIRLO): ZIRLO with a 100 micrometer inner molybdenum liner. Molybdenum k=138−0.0265*T W/(m*K), density 10,220 kg/m3.
Configuration 7 (Nb-lined ZIRLO): ZIRLO with a 100 micrometer inner niobium liner. Niobium k=52.3+0.0082*T W/(m*K), density 8,570kg/m3.
Configurations 8 through 10 (FGM SiC-ZIRLO): Functionally graded material with power-law volume fraction profile V_SiC(r)=((r-r_inner)/wall)^n, where n=0.5, 1.0, and 2.0 respectively. Inner surface is pure ZIRLO transitioning to pure SiC at the outer surface. Discretized into 10 sub-layers with rule-of-mixtures effective properties at each layer.
Configurations 11 through 13 (SiC Cermet): Silicon carbide particles dispersed in a zirconium matrix at volume fractions of 20%, 40%, and 60% respectively. Effective thermal conductivity computed using the Maxwell-Eucken model: k_eff=k_Zr*(k_SiC+2*k_Zr+2*V_SiC*(k_SiC−k_Zr))/(k_SiC+2*k_Zr−V_SiC*(k_SiC−k_Zr)).
Configurations 14 through 16 (Coated ZIRLO): ZIRLO substrate with 20 micrometer outer coatings of chromium oxide (Cr2O3), titanium aluminum nitride (TiAlN), or diamond-like carbon (DLC) respectively.

### Pressurized Water Coolant Properties

The pressurized water coolant properties at 15.5 MPa are computed using IAPWS-IF97 formulations over the operating temperature range of 550 K to 620 K. The coolant mass flux is 3,460kg/(m2*s) with an approximate velocity of 4.5 m/s.

### Crank-Nicolson Plus Thomas Algorithm Solver

The thermal solver discretizes the one-dimensional radial heat equation in cylindrical coordinates using the Crank-Nicolson method with implicitness parameter theta=0.5, providing second-order accuracy in time and unconditional stability. The spatial discretization employs 40 radial nodes per fuel pin: 20 nodes in the fuel pellet, 5 nodes in the helium gap, and 15 nodes in the cladding, producing a 40-point tridiagonal linear system at each time step.

The boundary conditions are: at the outer cladding surface, a convective boundary condition coupling to the pressurized water coolant with heat transfer coefficient computed from the Dittus-Boelter correlation enhanced by a mixing vane grid spacer factor of 1.05; at the fuel centerline, an adiabatic (zero heat flux) symmetry boundary condition. The helium gap thermal resistance is modeled including a Kennard jump distance of 9 micrometers for gas conduction.

The tridiagonal system is solved using the Thomas algorithm (LU decomposition for tridiagonal matrices), which requires O(N) operations per pin. On the GPU, all 264 fuel pins are solved simultaneously in parallel, with each GPU thread block handling one fuel pin Thomas algorithm sweep.

### Six-Group Delayed Neutron Kinetics

The neutron kinetics module solves the point kinetics equations with six delayed neutron precursor groups for uranium-235 thermal fission. The total delayed neutron fraction is beta=0.00650, and the prompt neutron generation time is Lambda=2.0e-5 seconds. Doppler temperature reactivity feedback is modeled with coefficient alpha_D=−2.80e-5 dk/k per Kelvin. Moderator temperature reactivity feedback is modeled with coefficient alpha_M=−145e-5 dk/k per percent void.

Time integration of the kinetics equations employs a second-order Runge-Kutta (RK2) scheme with the same time step as the thermal solver (dt=10 ms).

### LOCA Transient Analysis Module

The LOCA module implements a two-node lumped fuel-plus-cladding thermal model with three sequential phases: (1) blowdown phase simulating rapid depressurization and loss of coolant inventory; (2) refill phase simulating emergency core cooling system (ECCS) injection; and (3) reflood phase simulating core re-wetting and quench. The module computes peak cladding temperature (PCT), equivalent cladding reacted (ECR) percentage using Baker-Just kinetics with proper SI unit conversion (3,330 kg2/m4 rate constant), and departure from nucleate boiling ratio (DNBR) using the W-3 correlation in Todreas form.

All sixteen cladding configurations are evaluated against 10 CFR 50.46 acceptance criteria: PCT less than 1,477 K (2,200 degrees F.), ECR less than 17%, coolable geometry maintained, and long-term cooling capability assured.

### RIA Transient Analysis Module

The RIA module simulates a control rod ejection accident using six-group point kinetics with Doppler feedback. The module computes time-dependent reactor power, fuel temperature, and peak fuel enthalpy deposition. All sixteen configurations are verified to maintain peak fuel enthalpy below the NRC limit of 230 cal/g.

### Accident Sequencing Module

A finite state machine manages transitions between normal operation, LOCA, RIA, departure from nucleate boiling, and station blackout states based on monitored reactor parameters including pressure, temperature, neutron flux, and coolant flow rate. State transitions trigger the appropriate transient analysis module automatically.

### Closed-Loop PI Power Controller

The power controller employs a proportional-integral (PI) control law that modulates control rod position and coolant flow rate to maintain the target core outlet temperature of 598 K and reactor power at 800 MWt. The proportional gain is Kp=0.05 and the integral gain is Ki=0.005. The control loop operates at the simulation time step of 10 ms, providing 100 Hz control bandwidth.

### Monte Carlo Neutronics Coupling

The digital twin optionally couples to a Monte Carlo neutron transport code (OpenMC) using ENDF/B-VII.1 cross-section libraries to obtain pin-resolved power distributions and eigenvalue (k-effective) calculations for each cladding configuration. Validated k-effective values range from approximately 1.360 for FeCrAl cladding to 1.429 for SiC/SiC cladding, reflecting the varying neutron absorption characteristics of the sixteen cladding materials.

### GPU Implementation Details

The solver is implemented natively on GPU hardware using parallel thread blocks. Each of the 264 fuel pins is assigned to an independent thread block, with the 40-node Thomas algorithm sweep executing within a single thread block using shared memory for the tridiagonal coefficients. All data remains GPU-resident throughout the simulation, eliminating host-device memory transfer overhead.

Performance profiling demonstrates a median per-step computation time of approximately 2 to 3 ms with a p 95 latency below 10 ms, confirming real-time capability at the 10 ms control loop period. The implementation supports NVIDIA GPU architectures with compute capability 7.0 and above.

What is claimed is:

1. A GPU-accelerated digital twin system for real-time simulation and control of a land-based pressurized water reactor, comprising:
(a) a GPU computing device executing a Crank-Nicolson temporal discretization with Thomas algorithm tridiagonal solver, the solver computing radial temperature distributions across a plurality of fuel pins simultaneously in parallel, each fuel pin discretized into a plurality of radial nodes spanning a uranium dioxide fuel pellet region, a helium gas gap region, and a cladding region;
(b) a multi-material cladding thermal property module executing on the GPU computing device, the module computing temperature-dependent thermal conductivity, density, and specific heat capacity for each of a plurality of cladding material configurations including at least a zirconium alloy, a chromium-coated zirconium alloy, an iron-chromium-aluminum alloy, a silicon carbide composite, a functionally graded material, and a ceramic-metallic cermet;
(c) a six-group delayed neutron kinetics module executing on the GPU computing device, the kinetics module computing reactor power with Doppler temperature reactivity feedback and moderator temperature reactivity feedback based on volume-averaged fuel and coolant temperatures;
(d) a heat transfer coefficient computation module executing on the GPU computing device, the module computing convective heat transfer between the fuel pins and pressurized water coolant using a Dittus-Boelter correlation with mixing vane grid spacer enhancement factors; and
(e) a closed-loop controller executing on the GPU computing device, the controller modulating at least one of reactor power, control rod position, and coolant flow rate based on core outlet temperature feedback to maintain a target thermal power and outlet temperature, wherein the system achieves a p95 computational latency of less than 10 milliseconds per time step.

2. The system of claim 1, wherein the plurality of fuel pins comprises 264 fuel pins arranged in a 17 -by-17 square lattice assembly with 25 guide tube and instrument tube positions, each fuel pin comprising a uranium dioxide pellet with an enrichment of approximately 4.95 weight percent uranium-235, a pellet outer radius of approximately 4.40 millimeters, a helium gas gap of approximately 82.6 micrometers, and a total cladding wall thickness of approximately 571.5 micrometers.

3. The system of claim 1, wherein the multi-material cladding thermal property module supports at least sixteen distinct cladding configurations comprising:
(i) a ZIRLO zirconium alloy reference cladding;
(ii) a chromium-coated ZIRLO cladding;
(iii) an iron-chromium-aluminum alloy FeCrAl C26M cladding;
(iv) a silicon carbide fiber-reinforced silicon carbide matrix composite cladding;
(v) a chemical vapor deposition silicon carbide cladding with a zirconium inner liner;
(vi) a molybdenum-lined ZIRLO cladding;
(vii) a niobium-lined ZIRLO cladding;
(viii) a plurality of functionally graded silicon carbide-ZIRLO claddings with power-law grading exponents;
(ix) a plurality of silicon carbide particle-in-zirconium matrix cermet claddings with varying silicon carbide volume fractions; and
(x) coated ZIRLO claddings including chromium oxide, titanium aluminum nitride, and diamond-like carbon coatings.

4. The system of claim 1, wherein the pressurized water coolant operates at a system pressure of approximately 15.5 MPa, an inlet temperature of approximately 583 K, and an outlet temperature of approximately 598 K, and wherein subcooled water transport properties are computed as temperature-dependent and pressure-dependent correlations using IAPWS-IF97 formulations.

5. The system of claim 1, further comprising a loss-of-coolant accident transient analysis module executing on the GPU computing device, the LOCA module computing time-dependent peak cladding temperature, equivalent cladding reacted percentage, and departure from nucleate boiling ratio through blowdown, refill, and reflood phases, and verifying compliance with 10 CFR 50.46 acceptance criteria including a peak cladding temperature below 1,477 K and an equivalent cladding reacted percentage below 17 percent.

6. The system of claim 1, further comprising a reactivity-insertion accident analysis module executing on the GPU computing device, the RIA module computing six-group point kinetics with Doppler feedback during a control rod ejection transient and verifying that peak fuel enthalpy remains below 230 calories per gram in compliance with NRC regulatory limits.

7. The system of claim 1, further comprising a cladding oxidation and hydrogen generation module executing on the GPU computing device, the module computing cladding oxidation kinetics using at least one of a Baker-Just correlation for zirconium alloy claddings, a parabolic rate law for silicon carbide claddings, and material-specific oxidation rate reductions for coated and composite claddings.

8. A method for real-time thermal-hydraulic simulation and power control of a land-based pressurized water reactor, the method comprising:
(a) receiving, at a GPU computing device, current reactor state data including fuel pin temperature distributions, neutron precursor concentrations, and coolant conditions;
(b) selecting, from a stored library of at least sixteen cladding material configurations, temperature-dependent thermal properties for each fuel pin based on the cladding material installed in each fuel pin position;
(c) computing, on the GPU computing device using a Crank-Nicolson temporal discretization with Thomas algorithm tridiagonal solver, updated radial temperature profiles for each of a plurality of fuel pins simultaneously in parallel, including temperatures in a fuel pellet region, a gas gap region, and a cladding region;
(d) computing, on the GPU computing device, updated reactor power using six-group delayed neutron kinetics with Doppler temperature reactivity feedback and moderator temperature reactivity feedback;
(e) computing, on the GPU computing device, convective heat transfer coefficients between the fuel pins and pressurized water coolant with mixing vane grid spacer enhancement;
(f) evaluating, on the GPU computing device, departure from nucleate boiling ratio using a W-3 correlation to confirm adequate thermal margins;
(g) determining, by a closed-loop controller on the GPU computing device, adjusted control signals for at least one of reactor power and coolant flow rate based on a difference between a computed core outlet temperature and a target outlet temperature; and
(h) outputting the adjusted control signals to reactor control systems,
wherein steps (a) through (h) are completed within a p95 latency of less than 10 milliseconds.

9. The method of claim 8, further comprising executing a loss-of-coolant accident transient simulation comprising a blowdown phase, a refill phase, and a reflood phase, and computing peak cladding temperature and equivalent cladding reacted percentage for each of the at least sixteen cladding material configurations to verify compliance with 10 CFR 50.46 acceptance criteria.

10. The method of claim 8, further comprising executing a reactivity-insertion accident simulation using six-group point kinetics with Doppler feedback for a control rod ejection event, and verifying that peak fuel enthalpy remains below NRC regulatory limits for each of the at least sixteen cladding material configurations.

11. The method of claim 8, further comprising coupling the GPU-accelerated thermal-hydraulic solver to a Monte Carlo neutron transport code to obtain pin-resolved power distributions and eigenvalue calculations for each cladding configuration, and using the neutron transport results to update power peaking factors in the thermal-hydraulic solver.

12. The method of claim 8, wherein the method processes at least 69 fuel assemblies each containing 264 fuel pins for a total reactor thermal power of approximately 800 megawatts thermal, with a total peaking factor of approximately 2.50.

13. The method of claim 8, further comprising an accident sequencing module that automatically transitions between normal operation, loss-of-coolant accident, reactivity-insertion accident, departure from nucleate boiling, and station blackout states based on monitored reactor parameters.

14. A GPU computing system for real-time monitoring, control, and predictive safety assessment of a land-based nuclear power plant, the system comprising:
(a) a GPU processor;
(b) a non-transitory memory storing a digital twin model of the nuclear power plant, the digital twin model comprising a Crank-Nicolson plus Thomas algorithm thermal solver, a six-group delayed neutron kinetics solver with Doppler and moderator temperature reactivity feedback, a multi-material cladding property library supporting at least sixteen cladding configurations, a loss-of-coolant accident transient module, a reactivity-insertion accident transient module, and a closed-loop power controller;
(c) sensor input interfaces receiving reactor instrumentation data including temperature, neutron flux, coolant flow, and pressure measurements; and
(d) actuator output interfaces transmitting control commands to control rod drive mechanisms and coolant flow control systems,
wherein the system achieves real-time simulation and control with p95 latency below 10 milliseconds per time step.

15. The system of claim 14, wherein the digital twin model computes in real time compliance with 10 CFR 50.46 acceptance criteria including peak cladding temperature below 1,477 K, equivalent cladding reacted percentage below 17 percent, and departure from nucleate boiling ratio above 1.30 for each of the at least sixteen cladding configurations.

16. The system of claim 14, wherein the multi-material cladding property library computes effective thermal conductivity for functionally graded material claddings using a rule of mixtures with a power-law volume fraction profile, and for ceramic-metallic cermet claddings using a Maxwell-Eucken effective medium model.

17. A non-transitory computer-readable medium storing instructions that, when executed by a GPU processor, cause the GPU processor to perform a method for GPU-accelerated land-based nuclear reactor digital twin simulation and control, the method comprising:
(a) allocating GPU memory for radial temperature arrays for each of a plurality of fuel pins across fuel pellet, gas gap, and cladding regions, and for six delayed neutron precursor group concentrations;
(b) for each simulation time step, computing in parallel across all fuel pins updated radial temperature profiles using a Crank-Nicolson discretization solved by a Thomas algorithm, with temperature-dependent material properties selected from a library of at least sixteen cladding material configurations;
(c) computing updated reactor power using six-group point kinetics with Doppler and moderator temperature reactivity feedback;
(d) computing departure from nucleate boiling ratio using a W-3 correlation with mixing vane grid spacer enhancement;
(e) computing a control output for reactor power adjustment using a proportional-integral controller based on core outlet temperature; and
(f) evaluating at least one of a loss-of-coolant accident transient and a reactivity-insertion accident transient to verify compliance with 10 CFR 50.46 acceptance criteria and NRC fuel enthalpy limits.

18. The computer-readable medium of claim 17, wherein the instructions compute cladding oxidation kinetics and hydrogen generation rates for each cladding material configuration, applying material-specific hydrogen generation reduction factors ranging from 0.001 for silicon carbide composites to 1.0 for uncoated zirconium alloy claddings.

19. The computer-readable medium of claim 17, wherein the instructions manage GPU memory such that all fuel pin temperature arrays, kinetics variables, cladding material property tables, and controller state reside in GPU global memory throughout the simulation, with tridiagonal solver coefficients staged through GPU shared memory within each thread block.

20. The computer-readable medium of claim 17, wherein the instructions are scalable to different reactor sizes by adjusting the number of GPU thread blocks launched, enabling application to pressurized water reactor designs ranging from small modular reactors with fewer than 50 fuel assemblies to large commercial reactors with more than 200 fuel assemblies.
